(19) United States
(12) Patent Application Publication
(10) Pub. No.: US 2025/0293115 A1
(43) Pub. Date: Sep. 18, 2025

(54) ELECTRONIC PACKAGE AND MANUFACTURING METHOD THEREOF

(71) Applicant: SILICONWARE PRECISION INDUSTRIES CO., LTD., Taichung City (TW)

(72) Inventors: Chih-Hsien CHIU, Taichung City (TW); Ko-Wei CHANG, Taichung City (TW); Chia-Yang CHEN, Taichung City (TW); Chun-Sheng CHANG, Taichung City (TW); Chin-Chiang HE, Taichung City (TW); Chia-Chen CHIAO, Taichung City (TW)

(73) Assignee: SILICONWARE PRECISION INDUSTRIES CO., LTD., Taichung City (TW)

(21) Appl. No.: 18/790,871

(22) Filed: Jul. 31, 2024

(30) Foreign Application Priority Data
Mar. 18, 2024 (TW) 113109977

(51) Int. Cl. H01L 23/373; H01L 21/48; H01L 23/00; H01L 23/31; H01L 23/498; H01L 25/00; H01L 25/10

(52) U.S. Cl. CPC H01L 23/3738; H01L 21/4857; H01L 23/3107; H01L 23/49838; H01L 25/105; H01L 23/498; H01L 23/49816; H01L 24/16; H01L 24/32; H01L 24/73; H01L 25/50; H01L 2224/16225; H01L 2224/32225; H01L 2224/73204; H01L 2225/107

(57) ABSTRACT

An electronic package and a manufacturing method thereof are provided, in which an electronic element and an interposer plate are provided on a carrier structure, so that the interposer plate covers the electronic element, wherein the interposer plate is formed with an opening such that the electronic element is exposed from the opening, and a thermal conductive block contacting the electronic element is placed in the opening to provide a heat dissipation path for the electronic element via the thermal conductive block.

### BACKGROUND

### 1. Technical Field

The present disclosure relates to a semiconductor packaging process, and more particularly, to an electronic package and a manufacturing method thereof for a package stack.

### 2. Description of Related Art

With the vigorous development of portable electronic products in recent years, the development of various related products is also trending towards high density, high performance, lightness, thinness, shortness and smallness. To this end, the industry has developed various packaging styles that integrate multiple functions in order to meet the requirements of thin, light, compact and high-density electronic products. In order to improve electrical functions and save packaging space, different three-dimensional packaging technologies have been developed, such as fan out package on package (FO PoP) and the like, so as to cope with the substantial increase in the number of input/output ports on various chips, allowing to integrate integrated circuits with different functions into a single package structure. This packaging method can take advantage of the heterogeneous integration characteristics of system in package (SiP), and can integrate electronic elements with different functions, such as: a memory, a central processing unit, a graphics processor, an imaging application processor, etc., via stacking design to achieve system integration, and is suitable for use in various thin and light electronic products.

FIG. 1 is a schematic cross-sectional view of a conventional semiconductor package 1. As shown in FIG. 1, the semiconductor package 1 includes: a package substrate 10 equipped with a semiconductor chip 11, a circuit structure 14 stacked on the package substrate 10 via conductive pillars 13 and an encapsulating glue 15 covering the semiconductor chip 11, thereby a plurality of solder balls 17 are arranged on the bottom side of the package substrate 10, and a package module 19 is connected to the circuit structure 14 via a plurality of conductive elements 18.

However, the semiconductor chip 11 of the lower structure of the aforementioned semiconductor package 1 is covered in the encapsulating colloid 15. Therefore, if the heat generated during its operation cannot be effectively dissipated, the semiconductor package may be overheated or even damaged.

Therefore, how to overcome the various problems of the above-mentioned prior art has become an urgent issue to be solved.

### SUMMARY

In view of the various deficiencies of the prior art, the present disclosure provides an electronic package, which comprises: a carrier structure is defined with a first side and a second side opposite to the first side; an electronic element is provided on the first side of the carrier structure and electrically connected to the carrier structure; an interposer plate is provided on the first side of the carrier structure and electrically connected to the carrier structure, and covering the electronic element; and a thermal conductive block is provided on the electronic element.

The present disclosure further comprises a method for manufacturing an electronic package, which comprises: providing an electronic element on a carrier structure, wherein the carrier structure is defined with a first side and a second side opposite to the first side, and the electronic element is disposed on the first side of the carrier structure and is electrically connected to the carrier structure; providing and electrically connecting an interposer plate to the first side of the carrier structure, thereby the interposer plate covers the electronic element; and providing a thermal conductive block on the electronic element.

In the aforementioned electronic package and the manufacturing method thereof, the electronic element is provided on the carrier structure via a plurality of conductive bumps, and an underfill covering the plurality of conductive bumps is formed between the electronic element and the carrier structure.

In the aforementioned electronic package and the manufacturing method thereof, the interposer plate is formed with an opening to at least partially expose the electronic element and accommodate the thermal conductive block.

In the aforementioned electronic package and the manufacturing method thereof, the interposer plate has a first surface and a second surface opposite to the first surface, and a plurality of first conductive members and a plurality of second conductive members are respectively formed on the first surface and the second surface, thereby the interposer plate is connected to the carrier structure via the plurality of second conductive members.

In the aforementioned electronic package and the manufacturing method thereof, the plurality of first conductive members are solder pads or solder balls, and the plurality of second conductive members are solder balls or copper core balls.

In the aforementioned electronic package and the manufacturing method thereof, the thermal conductive block is a dummy Silicon.

In the aforementioned electronic package and the manufacturing method thereof, the electronic package further comprises an encapsulation body covering the electronic element, the interposer plate and the thermal conductive block.

In the aforementioned electronic package and the manufacturing method thereof, the electronic element is provided on the carrier structure via a plurality of conductive bumps, and the encapsulation body covers the plurality of conductive bumps.

In the aforementioned electronic package and the manufacturing method thereof, a side of the interposer plate is exposed from a side of the encapsulation body or the side of the interposer plate is still covered by the encapsulation body.

In the aforementioned electronic package and the manufacturing method thereof, a side of the interposer plate is exposed from a side of the encapsulation body or the side of the interposer plate is covered by the encapsulation body.

In the aforementioned electronic package and the manufacturing method thereof, the interposer plate has a first surface and a second surface opposite to the first surface, and a plurality of first conductive members and a plurality of second conductive members are respectively formed on the first surface and the second surface, thereby the interposer plate is connected to the carrier structure via the plurality of second conductive members, and the plurality of first conductive members are exposed from the encapsulation body.

In the aforementioned electronic package and the manufacturing method thereof, an upper end surface of the thermal conductive block and upper end surfaces of the plurality of first conductive members are flush with an upper surface of the encapsulation body.

In the aforementioned electronic package and the manufacturing method thereof, the upper end surfaces of the plurality of first conductive members protrude outwardly from the upper surface of the encapsulation body.

In the aforementioned electronic package and the manufacturing method thereof, the electronic package further comprises a plurality of conductive elements provided on the second side of the carrier structure.

In the aforementioned electronic package and the manufacturing method thereof, the electronic package further comprises a package module provided on the interposer plate.

In the aforementioned electronic package and the manufacturing method thereof, a plurality of the thermal conductive blocks are provided on the electronic element.

In the aforementioned electronic package and the manufacturing method thereof, the thermal conductive block protrudes outside a vertical projection range of the electronic element.

In the aforementioned electronic package and the manufacturing method thereof, a plurality of electronic elements are provided on the carrier structure, and at least one thermal conductive block is provided on each of the electronic elements.

As can be seen from the above, in the electronic package and its manufacturing method of the present disclosure, an interposer plate with an opening is provided on the lower carrier structure of the package stack structure, thereby the lower electronic element in the package stack structure is exposed from the opening of the interposer plate, and a thermal conductive block contacting the electronic element is placed in the opening to increase the heat capacity of the electronic element and provide a heat dissipation path.

### BRIEF DESCRIPTION OF THE DRAWINGS

FIG. 1 is a schematic cross-sectional view of a conventional semiconductor package.

FIG. 2A to FIG. 2I are schematic cross-sectional views illustrating a manufacturing method of an electronic package according to a first embodiment of the present disclosure.

FIG. 3 is a schematic cross-sectional view of the electronic package according to a second embodiment of the present disclosure.

FIG. 4 is a schematic cross-sectional view of the electronic package according to a third embodiment of the present disclosure.

FIG. 5 is a schematic cross-sectional view of the electronic package according to a fourth embodiment of the present disclosure.

FIG. 6A and FIG. 6B are schematic cross-sectional views of the electronic package according to a fifth embodiment of the present disclosure.

FIG. 7A and FIG. 7B are schematic cross-sectional views of the electronic package according to a sixth embodiment of the present disclosure.

FIG. 8 is a schematic cross-sectional view of the electronic package according to a seventh embodiment of the present disclosure.

FIG. 9 is a schematic cross-sectional view of the electronic package according to an eighth embodiment of the present disclosure.

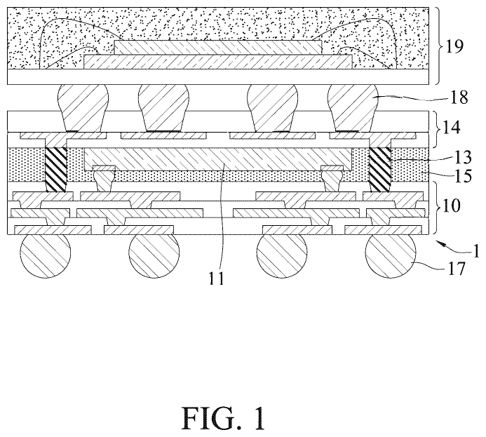

### DETAILED DESCRIPTIONS

The following describes the implementation of the present disclosure with examples. Those skilled in the art can easily understand other advantages and effects of the present disclosure from the contents disclosed in this specification.

It should be understood that, the structures, ratios, sizes, and the like in the accompanying figures are used for illustrative purposes to facilitate the perusal and comprehension of the contents disclosed in the present specification by one skilled in the art, rather than to limit the conditions for practicing the present disclosure. Any modification of the structures, alteration of the ratio relationships, or adjustment of the sizes without affecting the possible effects and achievable proposes should still be deemed as falling within the scope defined by the technical contents disclosed in the present specification. Meanwhile, terms such as “on,” “first,” “second,” “one” and the like used herein are merely used for clear explanation rather than limiting the practicable scope of the present disclosure, and thus, alterations or adjustments of the relative relationships thereof without essentially altering the technical contents should still be considered in the practicable scope of the present disclosure.

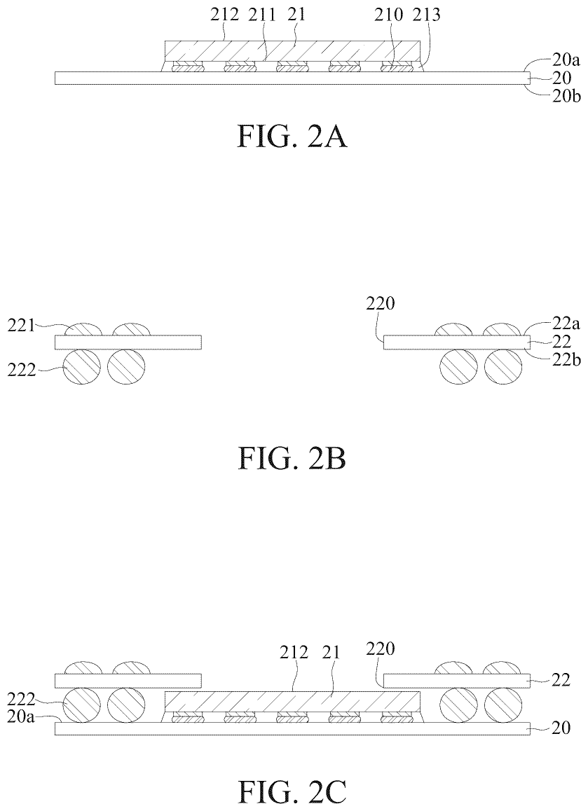

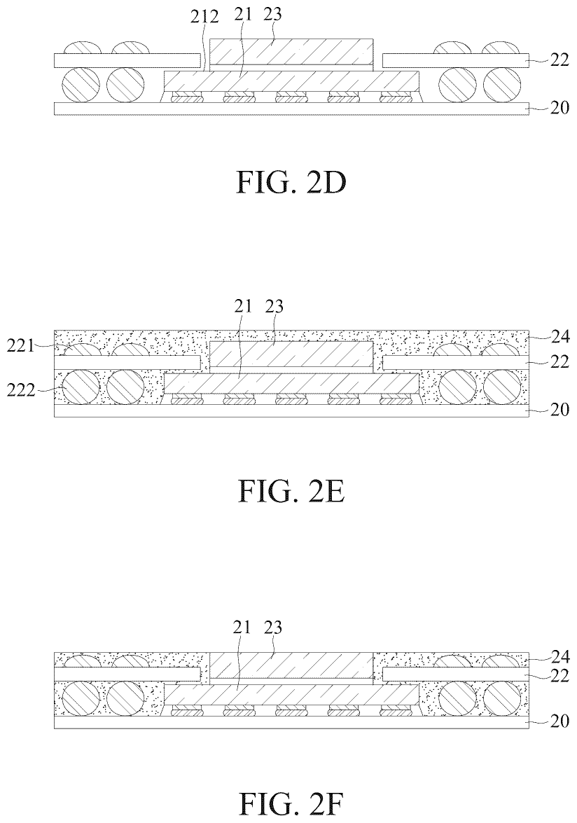

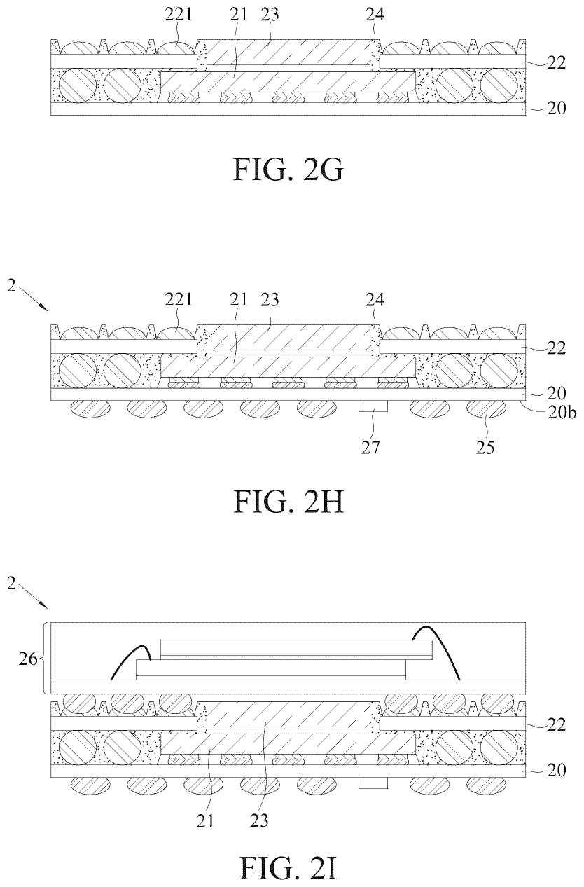

FIG. 2A to FIG. 2H are schematic cross-sectional views illustrating a manufacturing method of an electronic package according to a first embodiment of the present disclosure.

As shown in FIG. 2A, a chip placement operation is performed, and at least one electronic element 21 is connected to a carrier structure 20. The type of the carrier structure 20 can be a monolithic structure. To simplify the view, this view only shows a single carrier structure.

In one embodiment, the carrier structure 20 is, for example, a package substrate with a core layer or a coreless package substrate, wherein the carrier structure 20 has an insulating base and a wiring layer bonded to the insulating base, and is defined with a first side 20a and a second side 20b opposite to the first side 20a.

The electronic element 21 can be an active element, a passive element or a combination of both, and the like, wherein the active element is, for example, a semiconductor chip, and the passive element is, for example, a resistor, a capacitor, and an inductor. In one embodiment, the electronic element 21 is a semiconductor chip, which has an active surface 211 and a non-active surface 212 opposite to the active surface 211, wherein the electronic element 21 is disposed on the first side 20a of the carrier structure 20 in a flip-chip manner via a plurality of conductive bumps 210 of solder material and is electrically connected to the wiring layer, and wherein an underfill 213 is formed between the electronic element 21 and the carrier structure 20 to cover the plurality of conductive bumps 210. However, there are many ways for the electronic element to be electrically connected to the carrier structure and are not limited to the above.

As shown in FIG. 2B, at least one opening 220 is formed in an interposer plate 22, and a plurality of first conductive members 221 and a plurality of second conductive members 222 are provided on both sides of the interposer plate 22. The type of the interposer plate can be a monolithic structure. To simplify the view, this view only shows a single interposer plate.

In one embodiment, the interposer plate 22 has a first surface 22a and a second surface 22b opposite to the first surface 22a, so that a plurality of first conductive members 221 and a plurality of second conductive members 222 are respectively formed on the first surface 22a and the second surface 22b, wherein conductive vias (such as conductive silicon vias, not shown) connecting the first surface 22a and the second surface 22b are formed, allowing the first conductive members 221 and the second conductive members 222 on the first surface 22a and the second surface 22b can be electrically connected to each other via the conductive vias. In addition, the materials of the first conductive members 221 and the second conductive members 222 may be the same or different. For example, they are all solder balls, or each of the first conductive members 221 is a solder pad, and each of the second conductive members 222 is a solder ball.

As shown in FIG. 2C, the interposer plate 22 is mounted and electrically connected to the first side 20a of the carrier structure 20 via the plurality of second conductive members 222, and the position of the electronic element 21 corresponds to the position of the opening 220, thereby at least part of the inactive surface 212 of the electronic element is exposed from the opening 220.

As shown in FIG. 2D, at least one thermal conductive block 23 is mounted to the non-active surface 212 of the electronic element that is exposed from the opening 220. In one embodiment, the thermal conductive block 23 is, for example, a dummy Silicon.

As shown in FIG. 2E, an encapsulation body 24 covering the electronic element 21, the interposer plate 22, the thermal conductive block 23, the first conductive members 221 and the second conductive members 222 is formed on the carrier structure 20. In one embodiment, the side of the interposer plate 22 can be exposed from the side of the encapsulation body 24.

As shown in FIG. 2F, a thinning operation is performed, and part of the encapsulation body 24 (or even part of the thermal conductive block 23) is removed by, for example, grinding, thereby the thermal conductive block 23 is exposed from the encapsulation body 24.

As shown in FIG. 2G, a hole-opening operation is performed, such as laser hole-opening, thereby the plurality of first conductive members 221 are exposed from the encapsulation body 24. In addition, if the thermal conductive block 23 and the first conductive member 221 can be simultaneously exposed when part of the encapsulation body 24 is removed during the aforementioned thinning operation, the hole-opening operation can be omitted.

As shown in FIG. 2H, a ball planting operation is performed, and a plurality of conductive elements 25 such as solder balls and passive modules 27 are arranged on the second side 20b of the carrier structure 20, thereby producing the electronic package 2 of the present disclosure.

In addition, as shown in FIG. 2I, a package module 26 (for example, a memory module) can be further disposed on the interposer plate 22 to form a package stack structure.

Via the aforementioned manufacturing process, the present disclosure further discloses an electronic package 2, which includes a carrier structure 20; an electronic element 21 provided on the carrier structure 20; an interposer plate 22 provided on the carrier structure 20, wherein the interposer plate is formed with an opening 220 to at least partially expose the electronic element 21; and a thermal conductive block 23 is provided on the electronic element 21 and accommodated in the opening 220. In addition, a package module 26 can be further disposed on the interposer plate 22.

Therefore, the electronic package 2 and its manufacturing method of the present disclosure mainly provide an interposer plate 22 with an opening 220 on the carrier structure 20 provided with the electronic element 21, thereby the electronic element 21 is exposed from the opening 220, and a thermal conductive block 23 contacting the electronic element is placed in the opening to increase the heat capacity of the electronic element 21 and provide a heat dissipation path.

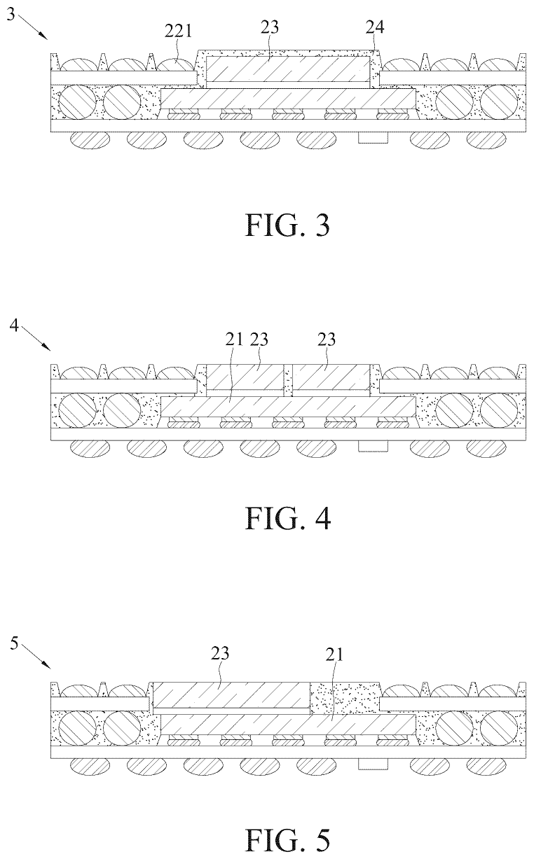

Please refer to FIG. 3, which is a schematic cross-sectional view of an electronic package according to a second embodiment of the present disclosure. The difference between this embodiment and the previous embodiment lies in the setting range of the encapsulation body. The other structures are roughly the same, so the similarities will not be described again.

As shown in FIG. 3, in the electronic package 3 of this embodiment, the encapsulation body 24 can cover the thermal conductive block 23, and only the first conductive members 221 are exposed from the encapsulation body 24.

Please refer to FIG. 4, which is a schematic cross-sectional view of an electronic package according to a third embodiment of the present disclosure. The difference between this embodiment and the previous embodiment lies in the number of thermal conductive blocks. The other structures are roughly the same, so the similarities will not be described again.

As shown in FIG. 4, in the electronic package 4 of this embodiment, a plurality of thermal conductive blocks 23 can be provided on the electronic element 21 to increase the heat capacity of the electronic element 21 and provide multiple heat dissipation paths.

Please refer to FIG. 5, which is a schematic cross-sectional view of an electronic package according to a fourth embodiment of the present disclosure. The difference between this embodiment and the previous embodiment lies in the placement position of the thermal conductive block. The other structures are roughly the same, so the similarities will not be described again.

As shown in FIG. 5, in the electronic package 5 of this embodiment, the thermal conductive block 23 provided on the electronic element 21 can protrude outside the vertical projection range of the electronic element, thereby the position of the thermal conductive block 23 is changed to meet the heat dissipation requirements of the electronic element 21.

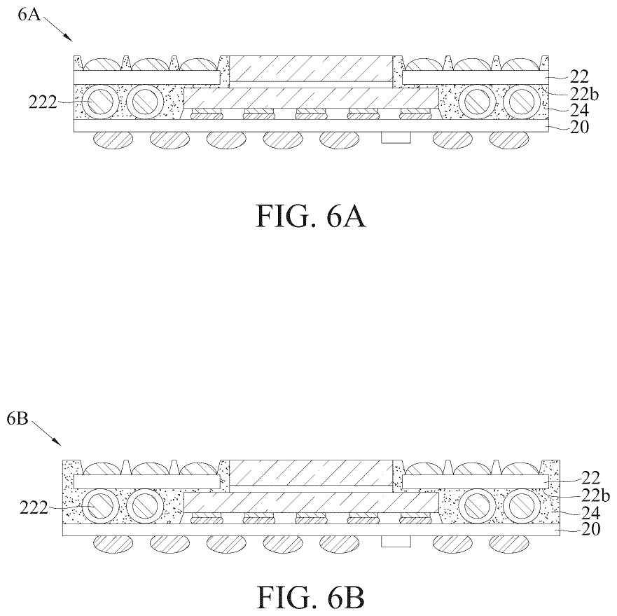

Please refer to FIG. 6A and FIG. 6B, which are schematic cross-sectional views of an electronic package according to a fifth embodiment of the present disclosure. The difference between this embodiment and the previous embodiment lies in the type of the second conductive member and the layout range of the interposer plate. The other structures are generally the same, so the similarities will not be described again.

As shown in FIG. 6A and FIG. 6B, in the electronic package 6A and the electronic package 6B of this embodiment, the plurality of second conductive members 222 disposed on the second surface 22b of the interposer plate 22 may be copper core balls to effectively maintain the distance between the interposer plate 22 and the carrier structure 20.

In addition, the side of the interposer plate 22 of the electronic package 6A can optionally be exposed from the side of the package 24, and the side of the interposer plate 22 of the electronic package 6B can be optionally covered in the encapsulation body 24 without being exposed.

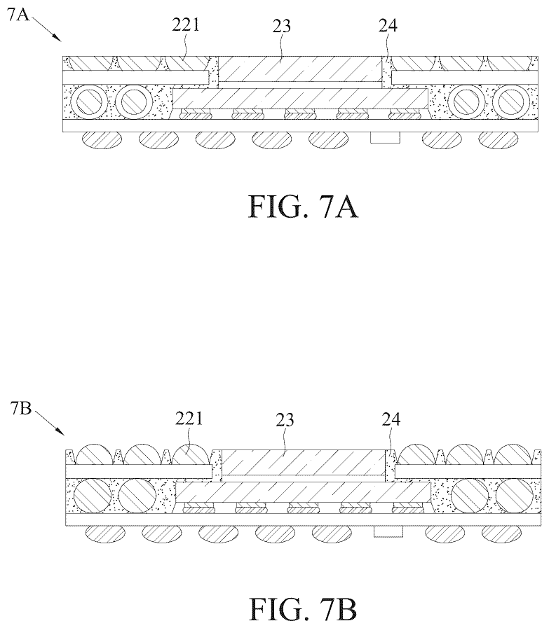

Please refer to FIG. 7A and FIG. 7B, which are schematic cross-sectional views of an electronic package according to a sixth embodiment of the present disclosure. The difference between this embodiment and the previous embodiment lies in the type of the first conductive member. The other structures are roughly the same, so the similarities will not be described again.

As shown in FIG. 7A, during the aforementioned thinning operation, part of the encapsulation body 24, part of the thermal conductive block 23 and part of each of the first conductive members 221 can be removed at the same time, thereby the thermal conductive block 23 and the plurality of first conductive members 221 of the electronic package 7A are exposed from the encapsulation body 24, and at the same time, the upper end surface of the thermal conductive block 23 and the upper end surfaces of the plurality of first conductive members 221 are flush with the upper surface of the encapsulation body 24.

Alternatively, for the electronic package 7B as shown in FIG. 7B, after the aforementioned thinning operation, the thermally conductive block 23 is exposed from the encapsulation body 24, and at the same time, the plurality of first conductive members 221 are exposed from the encapsulation body 24 via the aforementioned hole-opening operation, thereby the upper end surfaces of the plurality of first conductive members 221 protrude from the upper surface of the encapsulation body 24.

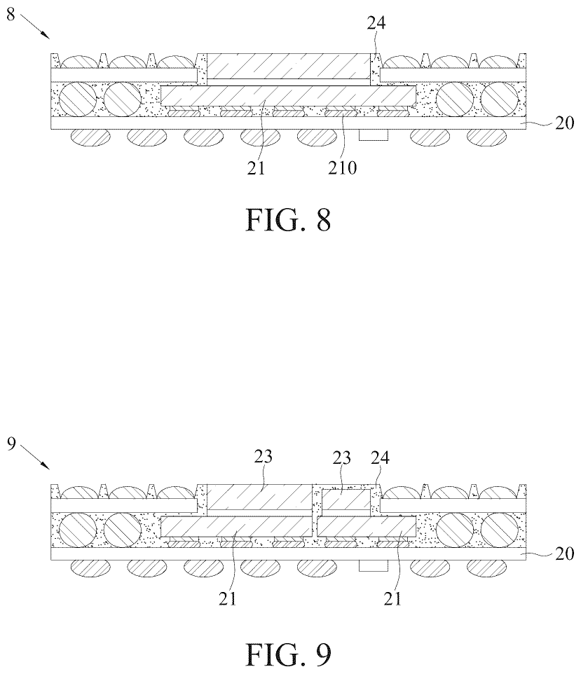

Please refer to FIG. 8, which is a schematic cross-sectional view of an electronic package according to a seventh embodiment of the present disclosure. This embodiment is substantially the same as the previous embodiment. In the electronic package 8 of this embodiment, no underfill is provided between the electronic element 21 and the carrier structure 20. Instead, the encapsulation body 24 is filled between the electronic element 21 and the carrier structure 20 and covers the conductive bumps 210.

Please refer to FIG. 9, which is a schematic cross-sectional view of an electronic package according to an eighth embodiment of the present disclosure. This embodiment is substantially the same as the previous embodiment. In the electronic package 9 of this embodiment, a plurality of electronic elements 21 are provided on the carrier structure 20, and at least one thermal conductive block 23 is provided on each of the electronic elements 21 to provide a good heat dissipation path for each of the electronic elements 21.

To sum up, in the electronic package and its manufacturing method of the present disclosure, an interposer plate with an opening is provided on the lower carrier structure of the package stack structure, thereby the lower electronic element in the package stack structure is exposed from the opening of the interposer plate, and a thermal conductive block contacting the electronic element is placed in the opening to increase the heat capacity of the electronic element and provide a heat dissipation path.

The foregoing embodiments are provided for the purpose of illustrating the principles and effects of the present disclosure, rather than limiting the present disclosure. Anyone skilled in the art can modify and alter the above embodiments without departing from the spirit and scope of the present disclosure. Therefore, the scope of protection with regard to the present disclosure should be as defined in the accompanying claims listed below.

What is claimed is:

1. An electronic package, comprising:
a carrier structure defined with a first side and a second side opposite to the first side;
an electronic element provided on the first side of the carrier structure and electrically connected to the carrier structure;
an interposer plate provided on the first side of the carrier structure and electrically connected to the carrier structure, and covering the electronic element; and
a thermal conductive block provided on the electronic element.

2. The electronic package of claim 1, wherein the electronic element is provided on the carrier structure via a plurality of conductive bumps, and an underfill covering the plurality of conductive bumps is formed between the electronic element and the carrier structure.

3. The electronic package of claim 1, wherein the interposer plate is formed with an opening to at least partially expose the electronic element and accommodate the thermal conductive block.

4. The electronic package of claim 1, wherein the interposer plate has a first surface and a second surface opposite to the first surface, and a plurality of first conductive members and a plurality of second conductive members are respectively formed on the first surface and the second surface, thereby the interposer plate is connected to the carrier structure via the plurality of second conductive members.

5. The electronic package of claim 4, wherein the plurality of first conductive members are solder pads or solder balls, and the plurality of second conductive members are solder balls or copper core balls.

6. The electronic package of claim 1, wherein the thermal conductive block is a dummy Silicon.

7. The electronic package of claim 1, further comprising an encapsulation body covering the electronic element, the interposer plate and the thermal conductive block.

8. The electronic package of claim 7, wherein the electronic element is provided on the carrier structure via a plurality of conductive bumps, and the encapsulation body covers the plurality of conductive bumps.

9. The electronic package of claim 7, wherein a side of the interposer plate is exposed from a side of the encapsulation body or the side of the interposer plate is still covered by the encapsulation body.

10. The electronic package of claim 7, wherein the thermal conductive block is exposed from the encapsulation body or the thermal conductive block is covered by the encapsulation body.

11. The electronic package of claim 7, wherein the interposer plate has a first surface and a second surface opposite to the first surface, and a plurality of first conductive members and a plurality of second conductive members are respectively formed on the first surface and the second surface, thereby the interposer plate is connected to the carrier structure via the plurality of second conductive members, and the plurality of first conductive members are exposed from the encapsulation body.

12. The electronic package of claim 11, wherein an upper end surface of the thermal conductive block and upper end surfaces of the plurality of first conductive members are flush with an upper surface of the encapsulation body.

13. The electronic package of claim 11, wherein the upper end surfaces of the plurality of first conductive members protrude outwardly from the upper surface of the encapsulation body.

14. The electronic package of claim 1, further comprising a plurality of conductive elements provided on the second side of the carrier structure.

15. The electronic package of claim 1, further comprising a package module provided on the interposer plate.

16. The electronic package of claim 1, wherein a plurality of the thermal conductive blocks are provided on the electronic element.

17. The electronic package of claim 1, wherein the thermal conductive block protrudes outside a vertical projection range of the electronic element.

18. The electronic package of claim 1, wherein a plurality of electronic elements are provided on the carrier structure, and at least one thermal conductive block is provided on each of the electronic elements.

19. A method for manufacturing an electronic package, comprising:
providing an electronic element on a carrier structure, wherein the carrier structure is defined with a first side and a second side opposite to the first side, and the electronic element is disposed on the first side of the carrier structure and is electrically connected to the carrier structure;
providing and electrically connecting an interposer plate to the first side of the carrier structure, in a manner that the interposer plate covers the electronic element; and
providing a thermal conductive block on the electronic element.

20. The method of claim 19, wherein the electronic element is provided on the carrier structure via a plurality of conductive bumps, and an underfill covering the plurality of conductive bumps is formed between the electronic element and the carrier structure.

21. The method of claim 19, wherein the interposer plate is formed with an opening to at least partially expose the electronic element and accommodate the thermal conductive block.

22. The method of claim 19, wherein the interposer plate has a first surface and a second surface opposite to the first surface, and a plurality of first conductive members and a plurality of second conductive members are respectively formed on the first surface and the second surface, thereby the interposer plate is connected to the carrier structure via the plurality of second conductive members.

23. The method of claim 22, wherein the plurality of first conductive members are solder pads or solder balls, and the plurality of second conductive members are solder balls or copper core balls.

24. The method of claim 19, wherein the thermal conductive block is a dummy Silicon.

25. The method of claim 19, further comprising forming an encapsulation body covering the electronic element, the interposer plate and the thermal conductive block.

26. The method of claim 25, wherein the electronic element is provided on the carrier structure via a plurality of conductive bumps, and the encapsulation body covers the plurality of conductive bumps.

27. The method of claim 25, wherein a side of the interposer plate is exposed from a side of the encapsulation body or the side of the interposer plate is still covered by the encapsulation body.

28. The method of claim 25, wherein the thermal conductive block is exposed from the encapsulation body or the thermal conductive block is covered by the encapsulation body.

29. The method of claim 25, wherein the interposer plate has a first surface and a second surface opposite to the first surface, and a plurality of first conductive members and a plurality of second conductive members are respectively formed on the first surface and the second surface, thereby the interposer plate is connected to the carrier structure via the plurality of second conductive members, and the plurality of first conductive members are exposed from the encapsulation body.

30. The method of claim 29, wherein an upper end surface of the thermal conductive block and upper end surfaces of the plurality of first conductive members are flush with an upper surface of the encapsulation body.

31. The method of claim 29, wherein the upper end surfaces of the plurality of first conductive members protrude outwardly from the upper surface of the encapsulation body.

32. The method of claim 19, further comprising providing a plurality of conductive elements on the second side of the carrier structure.

33. The method of claim 19, further comprising providing a package module on the interposer plate.

34. The method of claim 19, wherein a plurality of the thermal conductive blocks are provided on the electronic element.

35. The method of claim 19, wherein the thermal conductive block protrudes outside a vertical projection range of the electronic element.

36. The method of claim 19, wherein a plurality of electronic elements are provided on the carrier structure, and at least one thermal conductive block is provided on each of the electronic elements.
